(19) United States
(12) Patent Application Publication
(10) Pub. No.: US 2025/0364471 A1
(43) Pub. Date: Nov. 27, 2025

(54) Semiconductor Device

(71) Applicant: Hitachi Astemo, Ltd., Hitachinaka-shi, Ibaraki (JP)

(72) Inventors: Masako KATO, Tokyo (JP); Osamu IKEDA, Tokyo (JP); Shiro YAMASHITA, Hitachinaka-shi, Ibaraki (JP)

(21) Appl. No.: 18/873,767

(22) PCT Filed: May 10, 2023
(86) PCT No.: PCT/JP2023/017620

§ 371 Date: Dec. 11, 2024

(30) Foreign Application Priority Data
Jul. 20, 2022 (JP) 2022-115778

(51) Int. Cl. H01L 23/00

(52) U.S. Cl. CPC H01L 24/16; H01L 24/13; H01L 24/81; H01L 2224/13111; H01L 2224/16227; H01L 2224/16238; H01L 2224/16503; H01L 2224/8102; H01L 2224/81191; H01L 2224/81815

(57) ABSTRACT

A semiconductor device includes an electronic component and a board that are disposed opposite to each other in a first direction, and a solder that connects the electronic component and the board, in which the electronic component includes a first electrode on a surface facing the board, the board includes a second electrode on a surface facing the electronic component, the solder has a bonding portion that is an intermetallic compound at an interface with each of the electronic component and the board, the solder contains Sn as a main component, and a variation in thickness of the bonding portion in the first direction is less than 2 micrometers.

### TECHNICAL FIELD

The present invention relates to a semiconductor device.

### BACKGROUND ART

In recent years, for the purpose of size reduction, high density, and high functionality of electronic devices, size reduction and high density are required for semiconductor devices, and area array type packaged semiconductor devices such as a ball grid array (BGA) and a chip size package (CSP) are often used. In an area array type packaged semiconductor device, uniform electrodes and solder balls are formed on a back surface with a constant size, a constant area, and a constant pitch. In order to correspond these electrodes and solder balls, electrodes of a wiring board are also formed with a constant size, a constant area, and a constant pitch.

In the area array type packaged semiconductor device, an electrode and a solder ball are formed in advance by a package manufacturer, and the composition of the solder ball is generally Sn-3.0Ag-0.5Cu. By using the solder ball, preliminary solder is formed on the electrodes of the wiring board, and the packaged semiconductor device is mounted and heated, whereby solder bumps are formed, and the corresponding electrodes are bonded to each other. A large number of solder bumps can be arranged within a predetermined area by reducing the size and pitch, which is advantageous for size reduction and high density. Since the solder bump has a wiring length shorter than that of a structure connected via a lead, the solder bump is advantageous for high speed transmission and can achieve high performance. In response to the increasing demand for electronization, EV, and electromechanical integration of automobiles, it is conceivable that the opportunity of mounting in-vehicle electronic control device on a high-temperature portion around an engine or a motor increases.

PTL 1 discloses a mounting structure body as follows. The mounting structure body includes a BGA having a BGA electrode, a circuit board having a circuit board electrode, and a solder joint that is disposed on the circuit board electrode and is connected to the BGA electrode. The solder joint contains Cu having a Cu content of 0.6 mass % or more and 1.2 mass % or less, Ag having an Ag content of 3.0 mass % or more and 4.0 mass % or less, and Bi having a Bi content of 0 mass % or more and 1.0 mass % or less. (1) When the Cu content is in a range of 0.6 mass % or more and 0.91 mass % or less, an In content is (5.3+(6−(1.55×Cu content+4.428))) mass % or more and (6.8+(6−(1.57×Cu content+4.564))) mass % or less, and the remaining portion is formed of Sn, (2) when the Cu content is in a range of more than 0.91 mass % and 1.0 mass % or less, the In content is (5.3+(6−(1.55×Cu content+4.428))) mass % or more and 6.8 mass % or less, and the remaining portion is formed of Sn, (3) when the Cu content is in a range of more than 1.0 mass % and 1.2 mass % or less, the In content is 5.3 mass % or more and 6.8 mass % or less, and the remaining portion is formed of Sn. The solder joint satisfies any one of (1) to (3).

### CITATION LIST

### Patent Literature

PTL 1: JP 2016-111072 A

### SUMMARY OF INVENTION

### Technical Problem

In the invention disclosed in PTL 1, measures for void destruction are unclear.

### Solution to Problem

According to a first aspect of the present invention, a semiconductor device includes an electronic component and a board that are disposed opposite to each other in a first direction, and a solder that connects the electronic component and the board, in which the electronic component includes a first electrode on a surface facing the board, the board includes a second electrode on a surface facing the electronic component, the solder has a bonding portion that is an intermetallic compound at an interface with each of the first electrode and the second electrode, the solder contains Sn as a main component, and a variation in thickness of the bonding portion in the first direction is less than 2 micrometers.

### Advantageous Effects of Invention

According to the present invention, it is possible to suppress void destruction of a solder.

### BRIEF DESCRIPTION OF DRAWINGS

FIG. 1 is an external view of a semiconductor device.

FIG. 2 is a detailed view of a solder bump.

FIG. 3 is a view illustrating the presence or absence of an occurrence of a void destruction due to a difference in shape of a lower intermetallic compound.

FIG. 4 is a view illustrating a manufacturing process of the semiconductor device.

FIG. 5 is a view illustrating a result of a temperature cycle test in a second embodiment.

FIG. 6 is a view illustrating a result of a first temperature cycle test in a third embodiment.

FIG. 7 is a view illustrating a result of a second temperature cycle test in the third embodiment.

### DESCRIPTION OF EMBODIMENTS

### First Embodiment

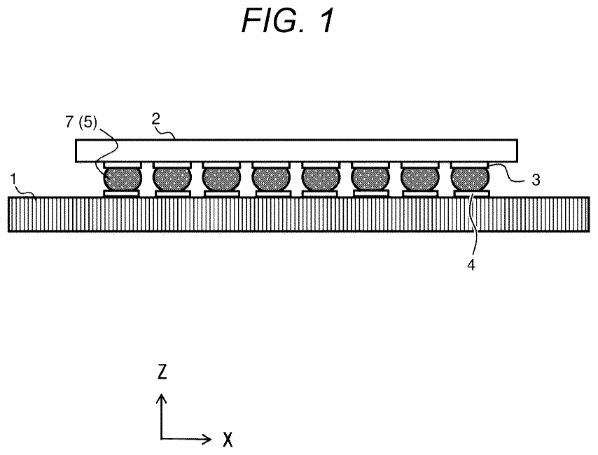

Hereinafter, a semiconductor device according to a first embodiment of will be described with reference to FIGS. 1 to 4.

The first embodiment will be described with reference to FIGS. 1 to 4. FIG. 1 is an external view of a semiconductor device 100. In order to clarify the correlation between the drawings, mutually orthogonal XYZ axes are defined. A Z-axis direction is also referred to as a “first direction” below. In FIG. 1, the back side is the Y-axis. As illustrated in FIG. 1, the semiconductor device 100 includes a wiring board 1 and a semiconductor package 2 that is an electronic component. The semiconductor package 2 is an area array type package. The wiring board 1 has a plurality of lower electrodes 4 on the upper surface. The semiconductor package 2 has a plurality of upper electrodes 3 on a lower surface thereof, and is mounted to face the plurality of lower electrodes 4 and the wiring board 1 via solder balls 5 provided in the upper electrodes 3 to form solder bumps 7. The upper electrode 3 is also referred to as a “first electrode”, and the lower electrode 4 is also referred to as a “second electrode”.

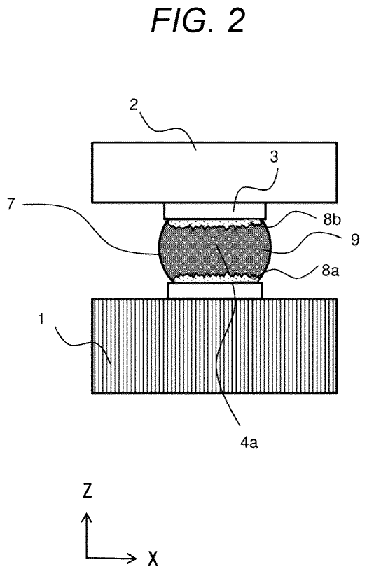

FIG. 2 is a detailed view of the solder bump 7 illustrated in FIG. 1. When a solder ball 5 and a solder paste 6 described later are heated and melted to form a solder bump 7, a lower intermetallic compound 8a is formed at an interface between the lower electrode 4 and the solder bump 7. Similarly, an upper intermetallic compound 8b is also formed at the interface between the upper electrode 3 and the solder bump 7. In the case of a BGA package, the upper intermetallic compound 8b is formed when the solder ball 5 is attached by a package manufacturer, and may be grown by heating and melting when the upper intermetallic compound 8b is connected to the wiring board 1. The lower intermetallic compound 8a and the upper intermetallic compound 8b are also referred to as “bonding portions” 8.

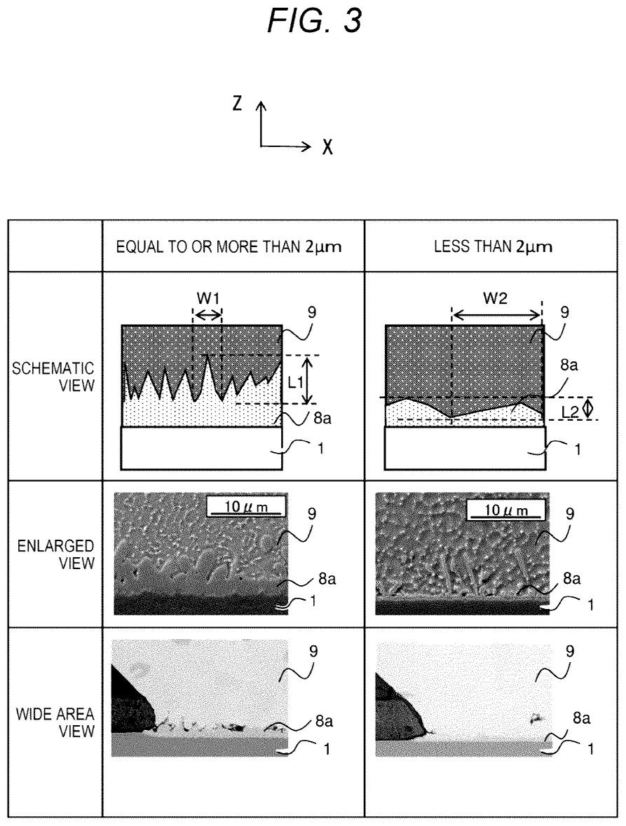

FIG. 3 is a view illustrating the presence or absence of an occurrence of void destruction due to a difference in shape of the lower intermetallic compound 8a. The left side of FIG. 3 illustrates a case where the variation in the thickness of the lower intermetallic compound 8a is 2 μm or more, and the right side of FIG. 3 illustrates a case where the variation in the thickness of the lower intermetallic compound 8a is less than 2 μm. The upper part of FIG. 3 is a schematic view, the middle part of FIG. 3 is an enlarged view, and the lower part of FIG. 3 is a wide area view. The enlarged view and the wide area view are actual observation results, and scales are the same on the left and right. Details of the middle part and the lower part will be described later. The variation in the thickness of the lower intermetallic compound 8a is a difference between the maximum value and the minimum value of the thickness of the lower intermetallic compound 8a, and is the length L1 and the length L2 in FIG. 3. The length L1 is 2 μm or more, and the length L2 is less than 2 μm.

When the variation in the thickness of the lower intermetallic compound 8a in the Z direction is 2 μm or more, it is conceivable that stress concentration is likely to occur, and microvoids are likely to be generated. On the other hand, when the variation in the thickness of the intermetallic compound in the Z direction is small, stress concentration is less likely to occur, and generation of microvoids is suppressed. The results of cross-section observation of a BGA bonding portion made of Sn-3.0Ag-0.5Cu for both the solder balls having a diameter of 0.8 mm and the solder paste 6 printed on the electrodes corresponding to the solder balls are illustrated in the middle part. On the other hand, a temperature cycle test in which the environmental temperature was alternately changed to −40° C. and 125° C. was performed for 500 cycles. The results of cross-section observation after 500 cycles are illustrated in the lower part.

When the variation in the thickness of the lower intermetallic compound 8a in the z direction was large, microvoids were generated at the interface between the bonding portion 8 and the lower intermetallic compound 8a after 500 cycles. On the other hand, when the variation in the thickness of the lower intermetallic compound 8a in the Z direction was small, microvoids were not generated at the interface between the bonding portion 8 and the lower intermetallic compound 8a after 500 cycles. Specifically, the size ratio of the lower intermetallic compound 8a in the width direction to that in the Z direction is 1:1 or less, which is smaller in the Z direction, and when the particle size in the Z direction is less than 2 μm, void destruction can be suppressed. However, the width direction of the lower intermetallic compound 8a is a dimension of a root portion of the lower intermetallic compound 8a, for example, W1 or W2 in the upper part. The Z direction of the lower intermetallic compound 8a is a dimension from the root portion to a vertex.

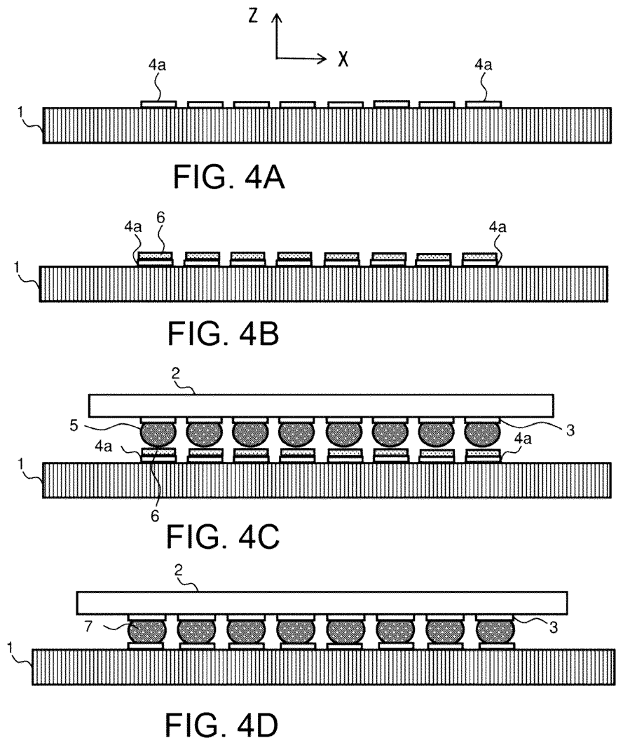

FIG. 4 is a view illustrating a manufacturing process of the semiconductor device 100. The semiconductor device 100 includes a wiring board 1 and a semiconductor package 2. As illustrated in FIG. 4(a), the wiring board 1 has a plurality of lower electrodes 4 on the upper surface, that is, the surface on the Z-axis plus side. As illustrated in FIG. 4(b), a solder paste 6 is formed on each of the lower electrodes 4. The solder paste 6 may be formed by printing or may be applied by a dispenser, and a forming method thereof is not limited thereto.

As illustrated in FIG. 4(c), the semiconductor package 2 including a plurality of upper electrodes 3 on the lower surface and solder balls 5 on the lower surface of the upper electrodes 3 is disposed on the solder paste 6. The semiconductor package 2 is disposed using, for example, a mounting machine. When the configuration illustrated in FIG. 4(c) is heated using a reflow furnace or the like, the semiconductor device 100 is formed as illustrated in FIG. 4(d). A solder bump 7 illustrated in FIG. 4(d) is formed by melting and cooling the solder ball 5 and the solder paste 6.

In order to reduce the particle size of the intermetallic compound, some measures such as optimization of a bonding profile, temperature control after bonding, optimization of metallization of members, and optimization of a solder composition used for soldering are required. Examples of the measure for member metallization include a method in which the member is bonded to either the surface or the underlaying with a Ni-plated electrode. In addition, as the measure for the solder composition used for soldering, the intermetallic compound may be a Ni—Sn compound alone, or a Cu—Sn compound and a Ni—Sn compound are contained in any ratio.

According to the first embodiment described above, it is possible to obtain the following operational effects.
(1) The semiconductor device 100 includes the semiconductor package 2 and the wiring board 1 that are disposed to face each other in the first direction, that is, the Z-axis direction, and the solder bump 7 that connects the semiconductor package 2 and the wiring board 1. The semiconductor package 2 includes the first electrode, that is, the upper electrode 3 on the surface facing the wiring board 1. The wiring board 1 includes the second electrode, that is, the lower electrode 4 on the surface facing the semiconductor package 2. The solder bump 7 has a bonding portion 8 that is an intermetallic compound at an interface with each of the upper electrode 3 and the lower electrode 4. The solder contains Sn as a main component. The variation in the thickness of the bonding portion 8 in the Z-axis direction is less than 2 micrometers. Therefore, as illustrated on the right side of FIG. 3, it is possible to suppress void destruction in the solder bump 7.

Conventionally, a problem has been known in which minute gaps (microvoids) are generated between the solder and the intermetallic compound under a high temperature environment, and, when these gaps are joined to each other, fractures are developed at an electrode interface, resulting in a decrease in life. In addition, it is also known that the solder bump is deformed at the time of temperature load due to a difference in linear expansion coefficient of each constituent member, stress is applied to the outermost solder bump of the BGA package, and a fracture develops in the solder. When fracture development in the solder occurs at the same time as the crack development at the electrode interface, the life until breakage of the solder bump is shortened, and the reliability is further impaired. However, in the semiconductor device 100 in the present embodiment, the variation in the thickness of the bonding portion 8 in the Z-axis direction is suppressed to less than 2 micrometers, so that it is possible to suppress void destruction in the solder bump 7 as illustrated on the right side of FIG. 3.
(2) The semiconductor package 2 and the solder form a ball grid array package. Therefore, the upper electrode 3 and the solder bump 7 are bonded in advance, and void destruction in the upper intermetallic compound 8b is less likely to occur.

### Second Embodiment

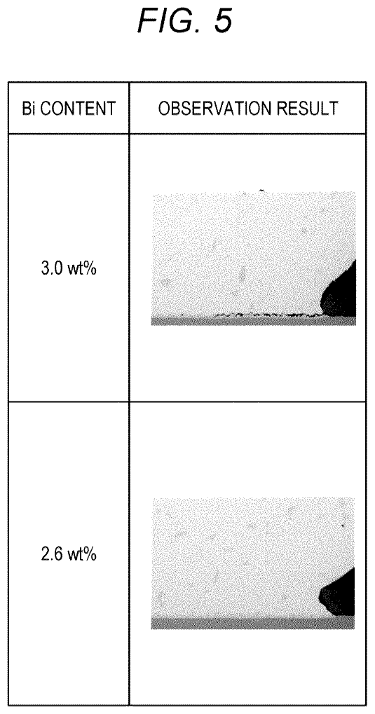

A semiconductor device according to a second embodiment will be described with reference to FIG. 5. In the following description, the same components as those of the first embodiment are denoted by the same reference signs, and differences will be mainly described. The points not specifically described are the same as those in the first embodiment. The present embodiment is different from the first embodiment mainly in the composition of the solder. In the first embodiment described above, the Bi (bismuth) content in the solder is not particularly limited. In the present embodiment, the content of Bi contained in the bonding portion 8 is defined.

FIG. 5 is a view illustrating results of a temperature cycle test when the content of Bi contained in the bonding portion 8 is 3.0 wt % and 2.6 wt %. The temperature cycle test is a test in which the environmental temperature is alternately changed to −40° C. and 125° C., and 500 cycles were performed. When the Bi content illustrated in the upper part of FIG. 5 was 3.0 wt %, microvoids were generated after the temperature cycle test, and the microvoids were joined to each other to cause fracture development. When the Bi content illustrated in the lower part of FIG. 5 was 2.6 wt %, microvoids were not generated even after the temperature cycle test. In any case, the variation in the thickness in the Z direction of the lower intermetallic compound 8a formed at the interface between the bonding portion 8 and the lower electrode 4 was 2 μm or more. Thus, even when the variation in the thickness of the bonding portion 8 in the Z direction is 2 μm or more, void destruction is suppressed when the Bi content in the bonding portion 8 is less than 3.0 wt %.

According to the second embodiment described above, it is possible to obtain the following operational effects.
(3) The semiconductor device 100 includes the semiconductor package 2 and the wiring board 1 that are disposed to face each other in the first direction, and the solder that connects the semiconductor package 2 and the wiring board 1. The semiconductor package 2 includes the first electrode, that is, the upper electrode 3 on the surface facing the wiring board 1. The wiring board 1 includes the second electrode, that is, the lower electrode 4 on the surface facing the semiconductor package 2. The solder bump 7 has a bonding portion 8 that is an intermetallic compound at an interface with each of the upper electrode 3 and the lower electrode 4. The solder bump 7 contains Sn as a main component. The variation in the thickness of the bonding portion 8 in the Z-axis direction is 2 micrometers or more, and the Bi content in the bonding portion 8 is less than 3.0 wt %. Therefore, as illustrated in the lower part of FIG. 5, even when the variation in the thickness of the bonding portion 8 in the Z-axis direction is 2 micrometers or more, it is possible to suppress void destruction by devising the composition of the solder.

### Third Embodiment

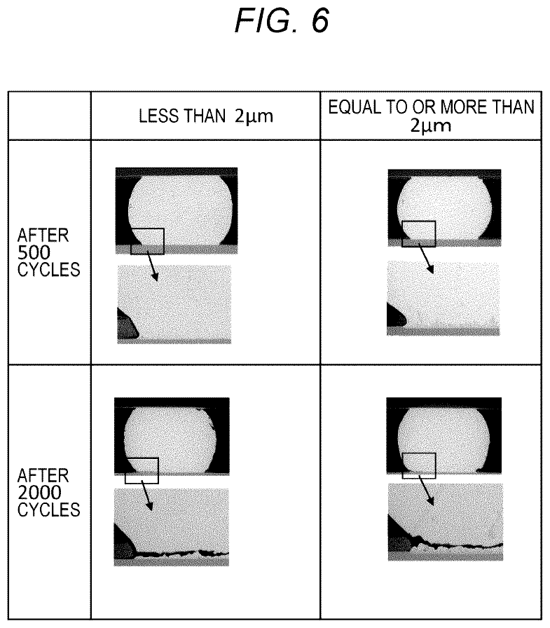

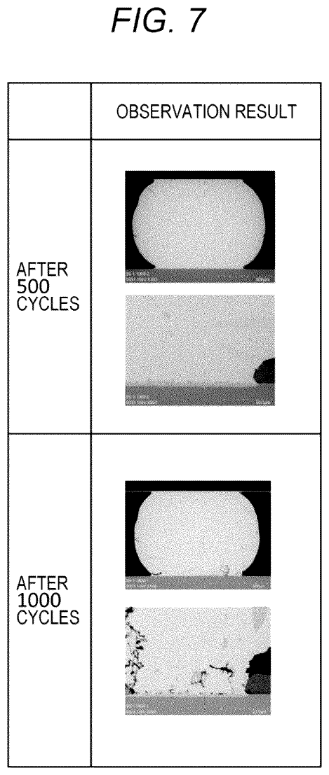

A semiconductor device according to a third embodiment will be described with reference to FIGS. 6 and 7. In the following description, the same components as those of the first embodiment are denoted by the same reference signs, and differences will be mainly described. The points not specifically described are the same as those in the first embodiment. The present embodiment is different from the first embodiment and the second embodiment mainly in the composition of the solder.

FIG. 6 is a view illustrating cycle test results when the composition of the bonding portion 8 is Sn-3.9Ag-0.5Cu-3.0Sb. FIG. 6 illustrates the case where the variation in the thickness in the Z direction of the lower intermetallic compound 8a formed at the interface between the bonding portion 8 and the lower electrode 4 is less than 2 μm, on the left side, and illustrates the case where the variation is 2 μm or more, on the right side. In this temperature cycle test, the environmental temperature was changed between −40° C. and 125° C. as in other embodiments. However, in the present embodiment, the observation was performed after 500 cycles and after 2000 cycles. In the observation results after 500 cycles illustrated in the upper part, microvoids were not generated regardless of the variation in the thickness of the lower intermetallic compound 8a in the Z direction. In the observation results after 2000 cycles illustrated in the lower part, fracture that develops in the bonding portion 8 due to thermal fatigue destruction were confirmed, but microvoids were not generated at the bonding interface.

FIG. 7 is a view illustrating cycle test results when the composition of the bonding portion 8 is Sn-4.0Ag-0.5Cu. That is, the bonding portion 8 illustrated in FIG. 7 does not contain Bi. In this case, the particle size of the lower intermetallic compound 8a formed at the interface between the bonding portion 8 and the lower electrode 4, in the Z direction, is 2 μm or more. In this temperature cycle test, similarly to the previous test, the environmental temperature was changed between −40° C. and 125° C., and the observation was performed after 500 cycles and after 1000 cycles.

As illustrated in FIG. 7, microvoids were not generated after 500 cycles, but microvoids were generated after 1000 cycles. In considering this result, FIG. 3 in the first embodiment is also used as the reference. As illustrated on the left side of FIG. 3, the composition of the bonding portion 8 was Sn-3.0Ag-0.5Cu, the variation in the thickness of the lower intermetallic compound 8a in the Z direction was 2 μm or more, and microvoids were generated by the temperature cycle test.

The following can be understood from the observation results illustrated in FIGS. 6 and 7 in the present embodiment and on the left side of FIG. 3 in the first embodiment. That is, since a large amount of Ag is contained in the solder, the Ag₃Sn network increases and the generation area of microvoids is dispersed, so that void destruction tends to be suppressed. However, it is conceivable that the deformation performance is increased by the solid solution strengthening of Sb, and the effect of suppressing microvoids at the bonding interface is greater when the stress acting on the particle boundary is relaxed. It can be understood that, when the bonding portion 8 does not contain Bi and the Sb content is 3.0 wt % or more, it is possible to suppress void destruction most.

According to the third embodiment described above, it is possible to obtain the following operational effects.
(4) The bonding portion 8 has a Bi content of less than 3.0 wt % and a Sb content of 3.0 wt % or more. Therefore, as illustrated in FIG. 6, it is possible to suppress the generation of microvoids regardless of the variation in the thickness of the bonding portion 8 in the Z direction.
(5) The variation in the thickness of the bonding portion 8 in the Z-axis direction is 2 micrometers or more, the bonding portion 8 does not contain Bi, and the Sb content is less than 3.0 wt %. Therefore, as illustrated in FIG. 7, void destruction is suppressed.

Although the present invention has been specifically described above based on examples, the present invention is not limited to the above examples, and various modifications can be made without departing from the gist of the present invention. In addition, the above embodiments are described in detail in order to explain the present invention in an easy-to-understand manner, and the above embodiments are not necessarily limited to a case including all the described configurations.

According to the present invention, an electronic control device incorporates a configuration in which an area array type package is connected to the wiring board 1 via the solder bumps 7. When the particle size in the Z direction of the intermetallic compound formed at the interface between the bonding portion 8 and the electrode is less than 2 μm, it is possible to suppress void destruction. Alternatively, even when the particle size of the intermetallic compound in the Z direction is 2 μm or more, it is sufficient that the composition of the bonding portion 8 does not contain Bi and the Sb content is 3.0 wt % or more. The dimensions, the ratio, and the shape of each of the components are not limited to the configuration in the drawings, and any constituent member such as the area array type package and the wiring board to be used is provided.

The above-described embodiments and modification examples may be combined. Although various embodiments and modification examples have been described above, the present invention is not limited to these contents. Other forms considered within the scope of the technical idea of the present invention are also included in the scope of the present invention.

### REFERENCE SIGNS LIST

1 wiring board
2 semiconductor package
3 upper electrode
4 lower electrode
5 solder ball
6 solder paste
7 solder bump
8 bonding portion
8a lower intermetallic compound
8b upper intermetallic compound
100 semiconductor device

1. A semiconductor device comprising:
an electronic component and a board that are disposed opposite to each other in a first direction; and
a solder that connects the electronic component and the board,
wherein the electronic component includes a first electrode on a surface facing the board,
the board includes a second electrode on a surface facing the electronic component,
the solder has a bonding portion that is an intermetallic compound at an interface with each of the first electrode and the second electrode,
the solder contains Sn as a main component, and
a variation in thickness of the bonding portion in the first direction is less than 2 micrometers.

2. The semiconductor device according to claim 1, wherein the electronic component and the solder form a ball grid array package.

3. A semiconductor device comprising:
an electronic component and a board that are disposed opposite to each other in a first direction; and
a solder that connects the electronic component and the board,
wherein the electronic component includes a first electrode on a surface facing the board,
the board includes a second electrode on a surface facing the electronic component,
the solder has a bonding portion that is an intermetallic compound at an interface with each of the first electrode and the second electrode,
the solder contains Sn as a main component,
a variation in thickness of the bonding portion in the first direction is 2 micrometers or more, and
a Bi content of the bonding portion is less than 3.0 wt %.

4. The semiconductor device according to claim 3, wherein the bonding portion has a Bi content of less than 3.0 wt % and a Sb content of 3.0 wt % or more.

5. A semiconductor device comprising:
an electronic component and a board that are disposed opposite to each other in a first direction; and
a solder that connects the electronic component and the board,
wherein the electronic component includes a first electrode on a surface facing the board,
the board includes a second electrode on a surface facing the electronic component,
the solder has a bonding portion that is an intermetallic compound at an interface with each of the first electrode and the second electrode,
the solder contains Sn as a main component,
a variation in thickness of the bonding portion in the first direction is 2 micrometers or more, and
the bonding portion does not contain Bi and has a Sb content of 3.0 wt% or more.
